(19) United States
(12) Patent Application Publication
(10) Pub. No.: US 2007/0087221 A1
(43) Pub. Date: Apr. 19, 2007

(54) Metal complex and organic electroluminescent device using the same

(75) Inventors: Pei-Chi Wu, Kaohsiung City (TW); Chung-Wen Ko, Sijhih City (TW)

Correspondence Address: RABIN & Berdo, PC, 1101 14TH STREET, NW, SUITE 500, WASHINGTON, DC, 20005, US

(73) Assignee: AU OPTRONICS CORP., Hsinchu (TW)

(21) Appl. No.: 11/527,590

(22) Filed: Sep. 27, 2006

(30) Foreign Application Priority Data
Oct. 19, 2005 (TW) 094136616
Mar. 8, 2006 (TW) 095107812

(51) Int. Cl. H01L 51/54; C09K 11/06

(52) U.S. Cl. 428/690; 428/917; 313/504; 313/506; 546/2; 546/4; 548/101; 548/103

(57) ABSTRACT

A metal complex incorporated in the organic electroluminescent device as a dopant in a light emitting layer, a hole transfer layer, or an electron blocking layer. The metal complex is represented by the formula 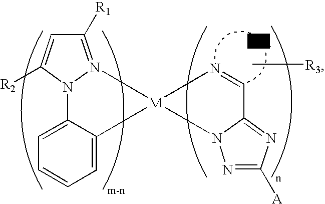
wherein M represents a transition metal whose atomic number of the periodic table is greater than 40; m is an integer equal to or smaller than the ligand numbers of M, n is an integer smaller than m; R₁, R₂, R₃, and A are independently selected from the group consisting of a halogen atom, a cyano group, a phenyl group, a heterocyclic group, a CF₃ group, a substituted or unsubstituted C1-C30 alkyl or alkoxy group, a hydroxy group, a thiol group, a substituted or un-substituted C2-C30 alkenyl group, a substituted or unsubstituted C6-C30 aryl group, and a haloalkyl group; Y₁ represents an atomic group having a nitrogen-containing heterocyclic ring.

This application claims the benefits of Taiwan Patent Application No. 94136616, filed Oct. 19, 2005 and Taiwan Patent Application No. 95107812, filed Mar. 8, 2006, the contents of which are herein incorporated by reference in its entirety.

### BACKGROUND OF THE INVENTION

1. Field of the Invention

The present invention relates in general to a metal complex and an organic electroluminescent device using the same, and more particularly, to a metal complex as a dopant in a light emitting layer of the organic electroluminescent device, or as an electron blocking layer between the light emitting layer and a hole transfer layer, or as a material of the hole transfer layer, for effectively improving electrical properties and emission efficiency of the organic electroluminescent device.

2. Description of the Related Art

Using of organic electroluminescence (OEL) devices are becoming increasingly desirable, and many of the transition metal complexes are applied as the electroluminescent materials. Luminescent materials including fluorescent material and phosphorescent material can be used for making a light emitting layer of an OEL device. But many researches have indicated that the emission efficiency of the phosphorescent material is much higher (about three times) than that of the fluorescent material. In the case of phosphorescence, the absorbed photon energy undergoes an unusual inter-system crossing into an energy state of higher spin multiplicity, usually is a triplet state and otherwise known as excited triplet state. Most phosphorescent compounds are relatively fast emitters, with triplet lifetimes on the order of milliseconds. However, some compounds have triplet lifetimes up to minutes or even hours, allowing these substances to effectively store light energy in the form of very slowly degrading excited electron states. If the phosphorescent quantum yield is high, these substances will release significant amounts of emission over long time scales. Thus, it is believed that the OEL device with high emission efficiency can be achieved through the development of the use of the phosphorescent material.

In the recent researches of the development of phosphorescent material, the transition metal complexes, particularly having transition metals with d⁶ electron in the centers thereof, are arousing industrial and academic interest. Examples of the transition metals suitable for being the center of the complexes include osmium (Os), platinum (Pt), iridium (Ir), ruthenium (Ru), and rhenium (Re). However, the known phosphorescent materials suffer from the difficulty of purification and sublimation. It usually takes a very long time to purify the phosphorescent compound, sometimes more than 10 days is required. Also, the time-consuming purification is likely to lead to the degradation and low-yield of phosphorescent compound. Generally, the yields of the known phosphorescent compounds are in a range of 30% to 40%.

### SUMMARY OF THE INVENTION

The present invention discloses a metal complex, for effectively improving electrical properties and increasing light efficiency of the applied organic electroluminescent device.

The present invention provides a metal complex represented by the formula (I):

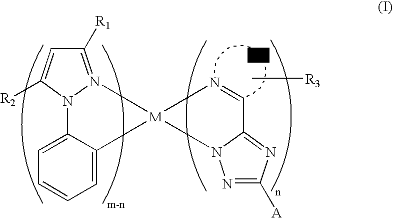

wherein M is a transition metal whose atomic number of the periodic table is greater than 40;

m is an integer equal to or smaller than a ligand number of M, and n is an integer smaller than m;

R₁, R₂, and R₃ are independently selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;

Y₁ is an atomic group having a nitrogen-containing heterocyclic ring;

A is selected from the group consisting of a halogen atom, a cyano group, a phenyl group, a heterocyclic group, a CF₃ group, a substituted or unsubstituted C₁-C30 alkyl group, a substituted or unsubstituted C₁-C30 alkoxy group, a hydroxy group, a thiol group, a substituted or unsubstituted C2-C30 alkenyl group, a substituted or unsubstituted C6-C30 aryl group, and a haloalkyl group.

The metal complex represented by the formula (I) can be incorporated in an organic electroluminescence (OEL) device as material of light emitting layer. The OEL device comprising an anode, a hole transport layer formed on the anode, an organic light emitting layer formed on the hole transport layer, an electron transport layer formed on the organic light emitting layer, and a cathode formed on the electron transport layer. The organic light emitting layer includes the metal coordination compound of formula (I).

The metal complex represented by the formula (I) can be further incorporated in an organic electroluminescence (OEL) device as material of an electron blocking layer. The OEL device comprising an anode, a hole transport layer formed above the anode, an electron blocking layer formed on the hole transport layer, an organic light emitting layer formed on the electron blocking layer, an electron transport layer formed on the organic light emitting layer, and a cathode formed on the electron transport layer. The electron blocking layer includes the metal complex of formula (I).

The metal complex represented by the formula (I) can be further incorporated in an organic electroluminescence (OEL) device as material of a hole transport layer. The OEL device comprising an anode, a hole transport layer formed on the anode, an organic light emitting layer formed on the hole transport layer, an electron transport layer formed on the organic light emitting layer, and a cathode formed on the electron transport layer. The hole transport layer includes the metal complex of formula (I).

Other objects, features, and advantages of the present invention will become apparent from the following detailed description of the preferred but non-limiting embodiments. The following description is made with reference to the accompanying drawings.

### BRIEF DESCRIPTION OF THE DRAWINGS

FIG. 1A, FIG. 1B respectively represent PL spectra of metal coordination compounds Ir-ppz1 and Ir-ppz2 in dichloromethane according to the embodiment of the present invention.

FIG. 2 schematically illustrates an organic electroluminescence (OEL) device according to the first example of EL device of the present invention.

FIG. 3 depicts the variation of current density with voltage according to the first example of EL devices A, B, C, and D of the present invention.

FIG. 4 depicts the variation of brightness with voltage according to the first example of EL devices A, B, C, and D of the present invention.

FIG. 5 depicts the variation of yield with current density according to the first example of EL devices A, B, C, and D of the present invention.

FIG. 6 depicts the variation of efficiency with current density according to the first example of EL devices A, B, C, and D of the present invention.

FIG. 7A depicts the variation of calorimetric data ClEx with voltage according to the first example of EL devices A, B, C, and D of the present invention.

FIG. 7B depicts the variation of calorimetric data ClEy with voltage according to the first example of EL devices A, B, C, and D of the present invention.

FIG. 8 represents the photoluminescence spectra of compound Ir-ppz1 and EL devices A, B, C, and D according to the first example of the present invention.

FIG. 9 schematically illustrates an organic electroluminescence (OEL) device according to the second example of EL device of the present invention.

FIG. 10 depicts the variation of current density with voltage according to the first set of EL devices STD, A, B, and C in the second example of the present invention.

FIG. 11 depicts the variation of brightness with voltage according to the first set of EL devices STD, A, B, and C in the second example of the present invention.

FIG. 12 depicts the variation of yield with current density according to the first set of EL devices STD, A, B, and C in the second example of the present invention.

FIG. 13 depicts the variation of efficiency with current density according to the first set of EL devices STD, A, B, and C in the second example of the present invention.

FIG. 14A depicts the variation of calorimetric data ClEx with voltage according to the first set of EL devices STD, A, B, and C in the second example of the present invention.

FIG. 14B depicts the variation of calorimetric data ClEy with voltage according to the first set of EL devices STD, A, B, and C in the second example of the present invention.

FIG. 15 represents the photoluminescence spectra of compound Ir-pytz and EL devices STD, A, B, and C according to the first set of EL devices in the second example of the present invention.

FIG. 16 depicts the variation of voltage with thickness of electron blocking layer according to the first set of EL devices STD, A, B, and C in the second example of the present invention, while the brightness of the EL devices achieve 1000 nits.

FIG. 17 depicts the variation of yield with current density according to the second set of EL devices STD, A, B, and C in the second example of the present invention.

FIG. 18 depicts the variation of yield with current density of the EL devices STD, A, B, and C according to the third example of the present invention.

### DETAILED DESCRIPTION OF THE INVENTION

In the present invention, a metal complex having advantages of easily sublimation tendency, thermal stability, rapid reaction and high production yield, is provided. The metal coordination compound can be applied in an organic electroluminescent device for being used as a dopant in a light emitting layer of the organic electroluminescent device, or used for making an electron blocking layer between the light emitting layer and a hole transfer layer, or used as a material of the hole transfer layer, in order to effectively improve electrical properties and increase emission efficiency of the organic electroluminescent device.

The metal coordination compound of the present invention is represented by the formula (I):

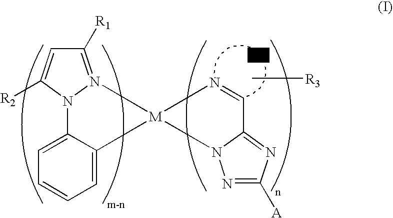

“M” represents a transition metal whose atomic number of the periodic table is greater than 40. Examples of M include osmium (Os), platinum (Pt), iridium (Ir), ruthenium (Ru), or rhenium (Re).

“m” is an integer equal to or smaller than the ligand numbers of M, and “n” is an integer smaller than m.

“R₁”, “R₂”, and “R₃” are selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group.

“Y₁” represents an atomic group forming a nitrogen-containing heterocyclic ring.

“A” is selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group.

Synthesis of two metal coordination compounds Ir-ppz1 and Ir-ppz2, having iridium (Ir) as the transition metal “M” of formula (I), are taken for illustration in the embodiment.

Synthesis of Metal Coordination Compound Ir-ppz1 (Formula (A))

A metal coordination compound Ir-ppz1 is represented by the formula (A):

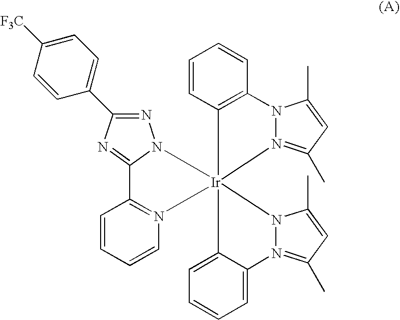

The metal coordination compound Ir-ppz1 can be prepared by the following procedure.

(1) Referring to the reaction of scheme A-1. First, 5 g (34.6 mmol) of phenyl hydrazine chloride was added to a round-bottom flask and dissolved in 30 ml of ethanol. Next, 3.8 g (38 mmol) of 6-pentane-2,4-dione was added drop-by-drop into the round-bottom flask, and well mixed. The solution in the round-bottom flask was refluxed for 6 hours. After cooling to room temperature, the resulting mixture was subjected to extraction by turn with ethyl acetate and water, and then vacuum dried to collect 4.88 g (28.4 mmol, yield 82%) of 3,5-dimethyl-phenyl-pyrazole (3,5-Me-ppz).

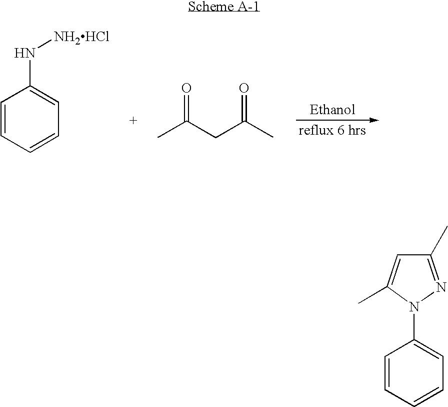

(2) Referring to the reaction of scheme A-2. 3.0 g (8.52 mmol) of IrCl₃ and 3.2 g (18.7 mmol) of 3,5-Me-ppz were added to a round-bottom flask containing a mixed solvent of 2-methoxyethanol and water (2-methoxyethanol: H₂O=3:1). The solution in the round-bottom flask was refluxed for 24 hours. Afterward, 20 ml of water is added to the round-bottom flask, and precipitate was observed. The resulting precipitate was filtered off, and washed with water followed by n-hexane, and then vacuum dried to collect 8.3 g (7.3 mmol, yield 85 %) of [(3,5-Me-ppz)₂Ir(μ-Cl)₂Ir(3,5-Me-ppz)₂].

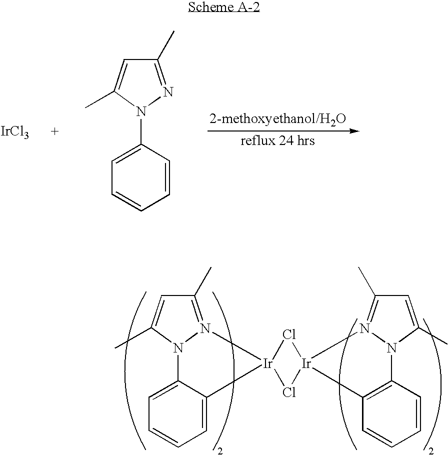

(3) Referring to the reaction of scheme A-3. 2.5 g (2.2 mmol) of [(3,5-Me-ppz)₂Ir(μ-Cl)₂Ir(3,5-Me-ppz)₂], 1.4 g (4.8 mmol) of [3-(4-trifluoromethyl-phenyl)]-5-(2-pyridyl)-1,2,4-triazole (CF3-Ph-PytzH) and excess potassium carbonate (K₂CO₃) were added to a round-bottom flask containing-2-methoxyethanol (solvent). The solution in the round-bottom flask was refluxed for 16 hours. Afterward, 20 ml of water is added to the round-bottom flask, and precipitate was observed. The resulting precipitate was filtered off, and washed with water followed by n-hexane, and then vacuum dried to collect the crude product. The crude product is placed in a sublimation column, and sublimated at a temperature of 290° C. and a pressure of 4×10⁻⁵ Torr to give 1.2 g (1.4 mmol, yield 65 %) of metal coordination compound Ir-ppz1 (formula (A)). 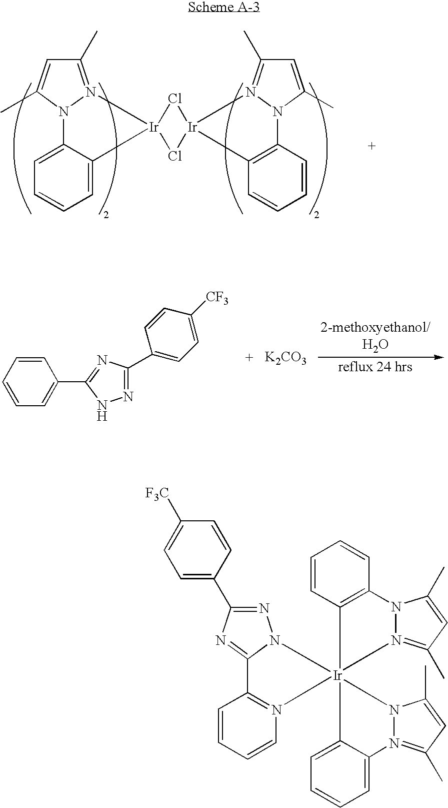
Synthesis of Metal Coordination Compound Ir-ppz2 (Formula (B))

A metal coordination compound Ir-ppz2 is represented by the formula (B):

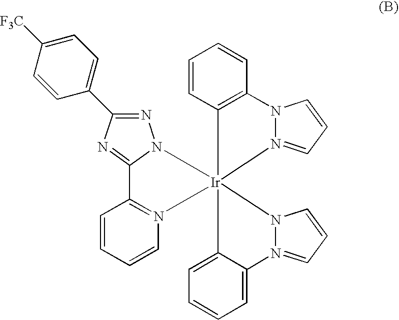

The metal coordination compound Ir-ppz2 can be prepared by the following procedure.

(1) Referring to the reaction of scheme B-1. 5.0 g (8.52 mmol).of IrCl₃ and 2.7 g (18.7 mmol) of phenyl-pyrazole (ppz) were added to a round-bottom flask containing a mixed solvent of 2-methoxyethanol and water (2-methoxyethanol:H₂O=3:1). The solution in the round-bottom flask was refluxed for 24 hours. Afterward, 20 ml of water is added to the round-bottom flask, and precipitate was observed. The resulting precipitate was filtered off, and washed with water followed by n-hexane, and then vacuum dried to collect 8.1 g (7.5 mmol, yield 88 %) of [(ppz)₂Ir(μ-Cl)₂Ir(ppz)₂].

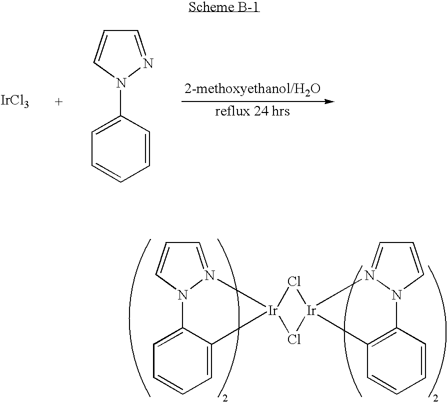

(2) Referring to the reaction of scheme B-2. 0.5 g (0.5 mmol) of [(ppz)₂Ir(μ-Cl)₂Ir(ppz)₂], 0.3g (1.1 mmol) of [3-(4-trifluoromethyl-phenyl)]-5-(2-pyridyl)-1,2,4-triazole (CF₃-Ph-PytzH) and excess potassium carbonate (K₂CO₃) were added to a round-bottom flask containing 2-methoxyethanol (solvent). The solution in the round-bottom flask was refluxed for 16 hours. Afterward, 20 ml of water is added to the round-bottom flask, and precipitate was observed. The resulting precipitate was filtered off, and washed with water followed by n-hexane, and then vacuum dried to collect the crude product. The crude product is placed in a sublimation column, and sublimated at a temperature of 295° C. and a pressure of 3×10⁻⁵ Torr to give 0.33 g (0.43 mmol, yield 85%) of metal coordination compound Ir-ppz2 (formula B).

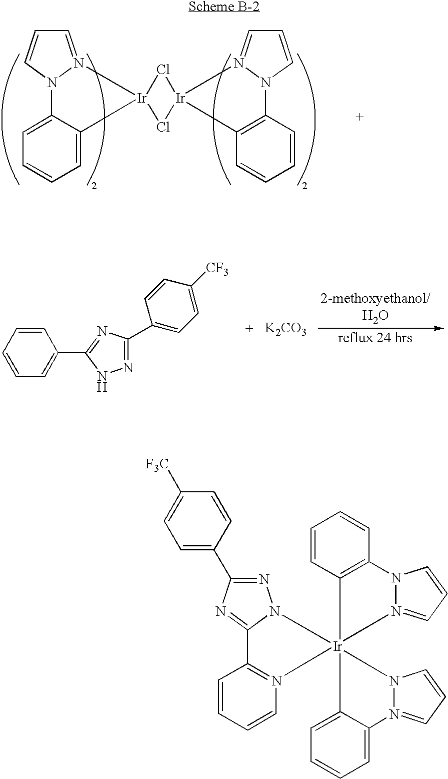

The metal coordination compounds of the invention, such as compounds Ir-ppz1 and Ir-ppz2, possess advantages of strong sublimation tendency, thermal stability, rapid reaction and high production yield. Accordingly, the crude product during synthesis can be purified in a short time (about 1 day for sublimation) and collected in high production yield. Also, no degradation occurs to the metal coordination compounds synthesized by the invention.

Experimental Results of Compounds Ir-ppz1 and Ir-ppz2

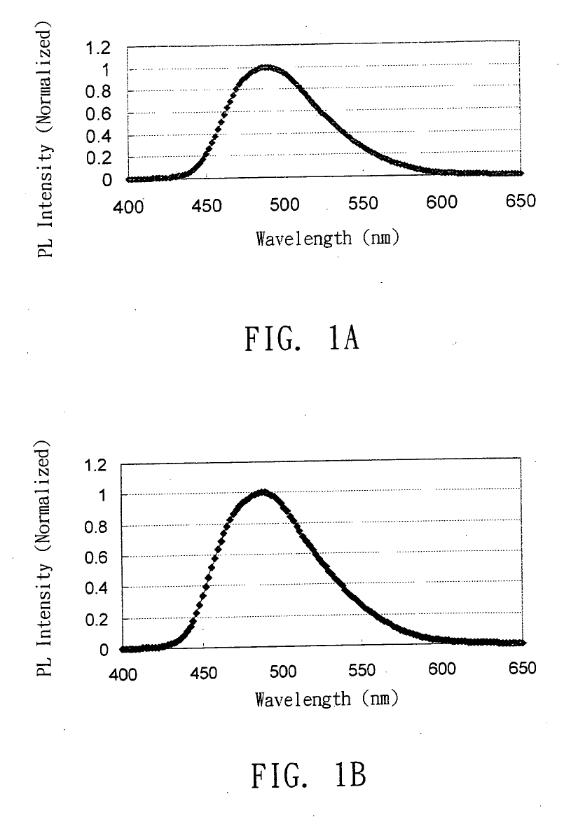

Photoluminescence (PL) spectra of the metal coordination compounds Ir-ppz1 and Ir-ppz2 in dilute solution of dichloromethane were measured on a fluorescence spectrophotometer (Hitachi F4500) at a room temperature. The experimental results are presented in FIG. 1A, FIG. 1B and Table 1.

FIG. 1A, FIG. 1B respectively represent PL spectra of metal coordination compounds Ir-ppz1 and Ir-ppz2 in dichloromethane according to the embodiment of the invention. The maximum wavelength of compounds Ir-ppz1 and Ir-ppz2 are both 490 nm, approximately. Colorimetric data, using appropriate mathematical function that have been defined by the International Lighting Commission (also known as Commission Internationale de l'Éclairage (CIE) value), were calculated based on the data of PL spectra. The CIE coordinates (ClEx, ClEy) of compounds Ir-ppz1 and Ir-ppz2 calculated based on the PL data are (0.15, 0.37) and (0.15, 0.36), respectively. Accordingly, compounds Ir-ppz1 and Ir-ppz2 have similar physical (such as electroluminescence) properties.

TABLE 1

| Compound | Maximum Wavelength | CIEx, CIEy |
|---|---|---|
| Ir-ppz1 | 490 nm | (0.15, 0.37) |
| Ir-ppz2 | 490 nm | (0.15, 0.36) |

The metal coordination compounds of the invention can be applied in an organic electroluminescent (EL) device. In the following EL device examples, the metal coordination compound Ir-ppz1 is used as a dopant in a light emitting layer of the EL device (see first example of EL device), and used as material of an electron blocking layer between the light emitting layer and a hole transfer layer of EL device (see second example of EL device), and used as a material of the hole transfer layer of EL device (see third example of EL device). Also, test results of the EL devices indicated that existence of the metal coordination compound of the invention does improve the electrical properties and light efficiencies of the EL devices.

### FIRST EXAMPLE OR EL DEVICE

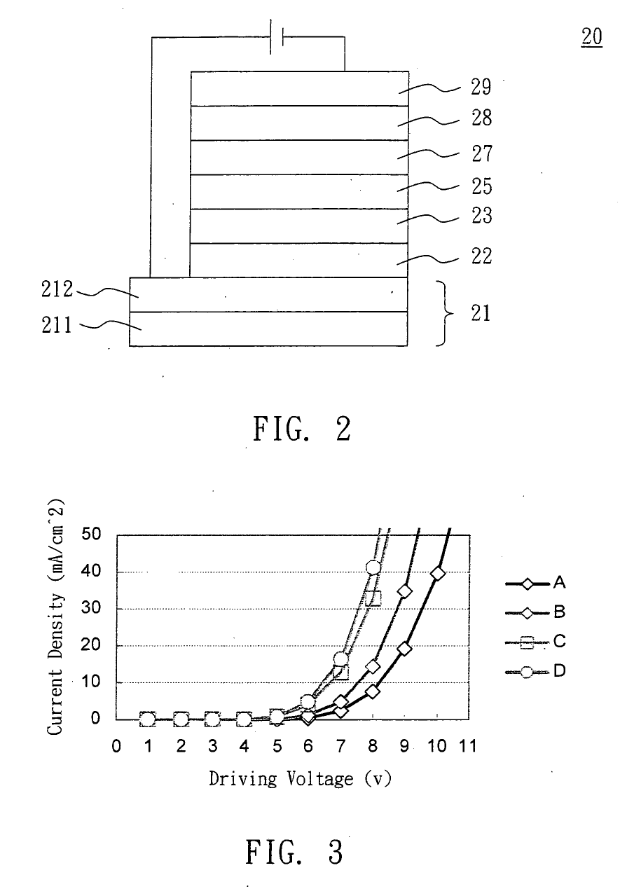

FIG. 2 schematically illustrates an organic electroluminescence (OEL) device according to the first example of EL device of the invention. A light emitting layer of the EL device is doped with the metal coordination compound Ir-ppz1.

As shown in FIG. 2, the OEL device 20 mainly includes an anode 21, a light emitting 25 and a cathode 29. For making the anode 21, a glass substrate 211 with an indium tin oxide (ITO) film 212 was provided and then washed by cleaning agent, acetone, and ethanol with ultrasonic agitation. After drying with nitrogen flow, the ITO film 212 was subjected to uv/ozone treatment. The cathode 29 could be a multi-metallic layer including lithium fluoride (LiF) and aluminum (Al). Also, a hole injection layer (HIL) 22 and a hole transport layer (HTL) 23 are formed between the anode 21 and the light emitting layer 25. An electron transport layer (ETL) 27 and an electron injection layer (EIL) 28 are formed between the cathode 29 and the light emitting layer 25. It is, of course, understood that the HIL 22 and the EIL 28 are not necessary to the OEL device, but can be existed for increasing injection ability of the electrons and holes.

In the first example, CDBP and the metal coordination compound Ir-ppz1 are selected as a host material and a dopant of the light emitting layer 25 of EL devices, respectively.

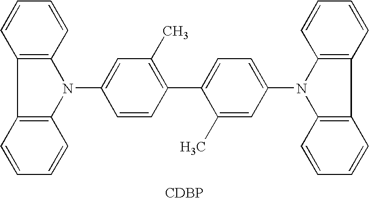

Four organic EL devices A, B, C and D are developed in the first example, and can be simply represented as follows. The light emitting layers of EL devices A, B, C and D, all 30 nm in thickness, are doped by compound Ir-ppz1 with different concentrations.

| | |
|---|---|
| Device A | Glass substrate/ITO/HIL/HTL/3 vol. % of compound Ir-ppz1: |
| | CDBP (30 nm)/ETL (45 nm)/LiF—Al |
| Device B | Glass substrate/ITO/HIL/HTL/6 vol. % of compound Ir-ppz1: |
| | CDBP (30 nm)/ETL (45 nm)/LiF—Al |
| Device C | Glass substrate/ITO/HIL/HTL/12 vol. % of compound |
| | Ir-ppz1: CDBP (30 nm)/ETL (45 nm)/LiF—Al |
| Device D | Glass substrate/ITO/HIL/HTL/15 vol. % of compound |
| | Ir-ppz1: CDBP (30 nm)/ETL (45 nm)/LiF—Al |

Device tests are conducted in the first example, and the results are presented in FIGS. 3, 4, 5, 6, 7A, 7B and 8.

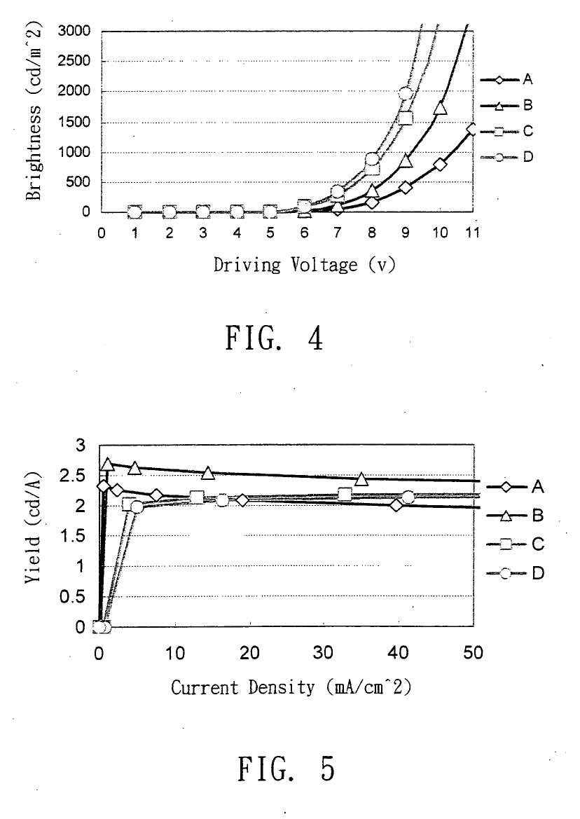

FIG. 3 depicts the variation of current density with voltage according to the first example of EL devices A, B, C and D of the invention. FIG. 4 depicts the variation of brightness with voltage according to the first example of EL devices A, B, C and D of the invention. The results of FIG. 3 indicated that injection ability of the electrons/holes of the devices increases with the dopant concentration. The injection ability of the electrons/holes is proportional to the dopant concentration, and device D possesses the best injection ability. The results of FIG. 4 indicated that the brightness of the devices also increases with the dopant concentration. The device D generates the brightness of 1000 nits (cd/m²) when a driving voltage is 8V. However, higher driving voltages are required for the devices A, B and C to generate the brightness of 1000 nits. Accordingly, the brightness of the device is also proportional to the dopant concentration.

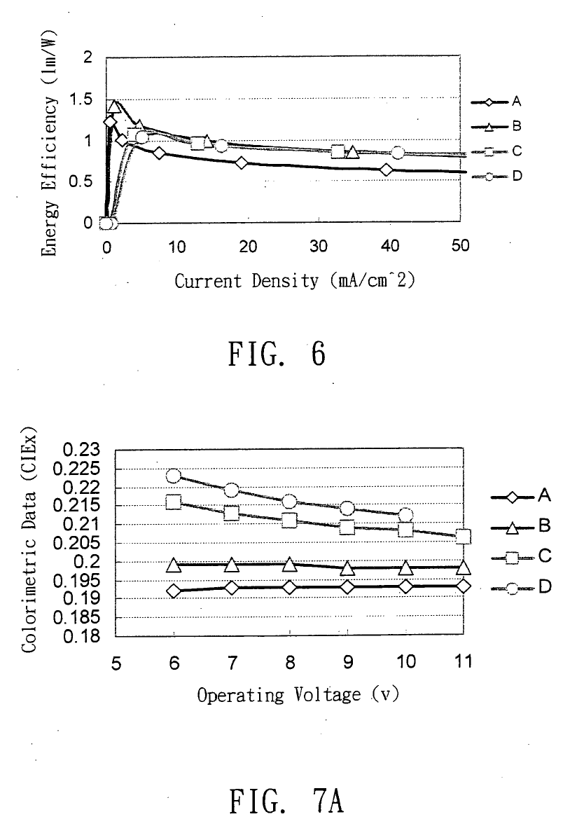

FIG. 5 depicts the variation of yield with current density according to the first example of EL devices A, B, C and D of the invention. FIG. 6 depicts the variation of efficiency with current density according to the first example of EL devices A, B, C and D of the invention. The results of FIG. 5 indicated that the device B (dopant concentration of 6%) has greatest yield (about 2.7 cd/A) than other devices, and the device A (dopant concentration of 3%) took second place. Similarly, the results of FIG. 6 indicated that the device B has highest efficiency and the device A took second place. Accordingly, high concentration dopant may have effect on electroluminescence mechanism of light emitting layer, so as to decrease the yield and the energy efficiency of the EL device. According to the experimental results, it is suggested that the light emitting layer is preferably doped with the compound Ir-ppz1 in a volume concentration between 6% to 9%, to obtain the higher yield and the efficiency.

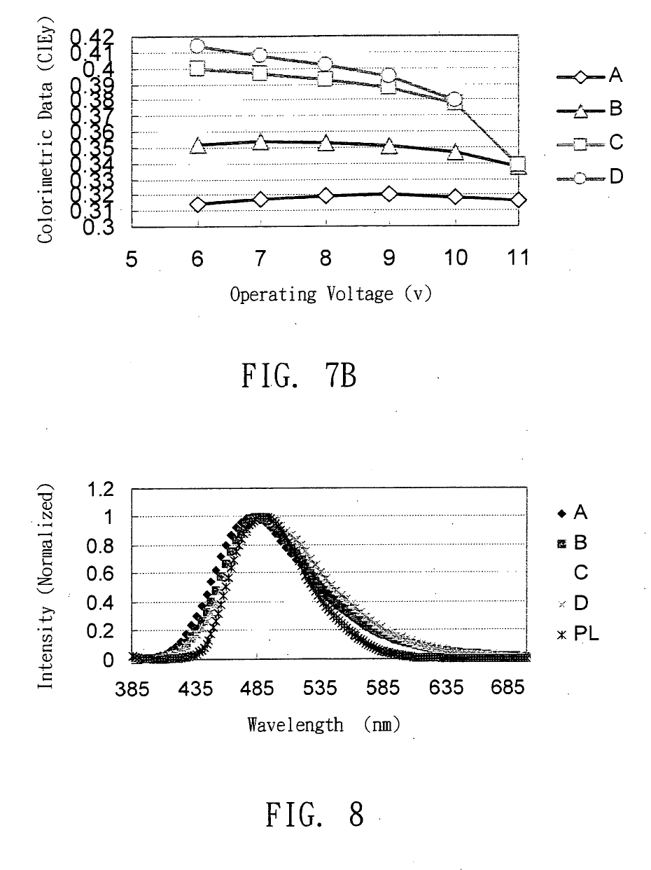

FIG. 7A depicts the variation of calorimetric data ClEx with voltage according to the first example of EL devices A, B, C and D of the invention. FIG. 7B depicts the variation of colorimetric data ClEy with voltage according to the first example of EL devices A, B, C and D of the invention. The results of FIG. 7A and FIG. 7B indicated that the calorimetric data ClEx and ClEy increase with the dopant concentration, but decrease with operating voltage.

FIG. 8 represents the photoluminescence spectra of compound Ir-ppz1 and EL devices A, B, C and D according to the first example of the invention. The results of FIG. 8 indicated that the maximum wavelengths of the devices A, B, C and D are 480 nm, 488 nm, 492 nm and 492 nm, respectively. Also, the device with higher dopant concentration has tendency to generate the maximum wavelength close to the red-shift. The photoluminescence spectra of compound Ir-ppz1 (depicted in curve “PL”) generate the maximum wavelength (of 490 nm) close to the blue-shift. The peaks of the curves depicting device A (dopant concentration of 3%, maximum wavelength of 480 nm) and compound Ir-ppz1 (curve “PL”, maximum wavelength of 490 nm) are 10 nm apart.

### SECOND EXAMMPLE OR EL DEVICE

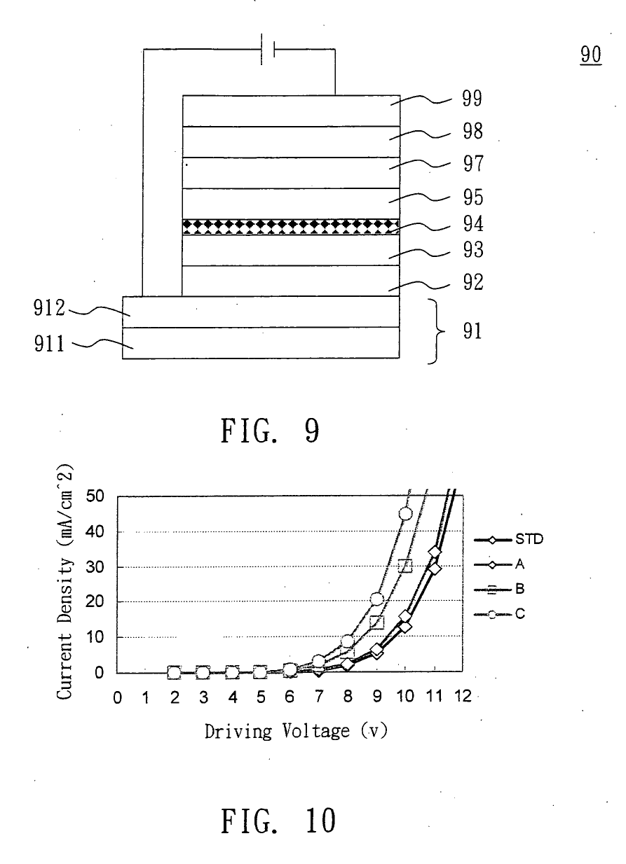

FIG. 9 schematically illustrates an organic electroluminescence (OEL) device according to the second example of EL device of the invention. An electron blocking layer (EBL) made of metal coordination compound Ir-ppz1 is further disposed between the light emitting layer and a hole transfer layer.

As shown in FIG. 9, an OEL device 90 mainly includes an anode 91, a light emitting layer 95 and a cathode 99. For making the anode 91, a glass substrate 911 is coated with an indium tin oxide (ITO) film 912. The cathode 99 could be a multi-metallic layer including lithium fluoride (LiF) and aluminum (Al). Also, a hole injection layer (HIL) 92, a hole transport layer (HTL) 93 and an electron blocking layer (EBL) 94 are formed between the anode 91 and the light emitting layer 95. An electron transport layer (ETL) 97 and an electron injection layer (EIL) 98 are formed between the cathode 99 and the light emitting layer 95. It is, of course, understood that the HIL 92 and the EIL 98 are optionally disposed in the OEL device 90.

In the second example, the metal coordination compound Ir-ppz1 is selected as material of making the electron blocking layer (EBL) 94, and several EL devices emitting blue light and green light are constructed for testing the yield and physical properties. The experimental details and results are described below. In a first set of EL devices, the light emitting layers are made of blue phosphorescent material such as Ir-pytz (described later) to emit blue light. In a second set of EL devices, the light emitting layers are made of green phosphorescent material to emit green light.

First Set of EL Devices (Emitting Blue Light)

In the first set of EL devices, the electron blocking layer 94 is made of compound Ir-ppz1, CDBP and compound Ir-pytz are respectively selected as a host material and a dopant of the light emitting layer 95 of EL devices. Compound Ir-pytz synthesis is described later (in the end of the second example).

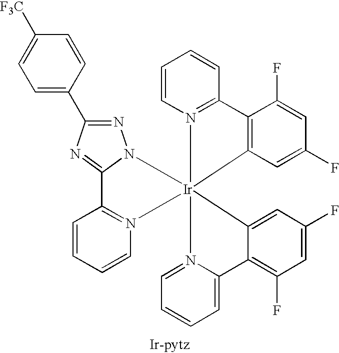

Four organic EL devices, including comparison device STD, devices A, B and C, are developed in the first set of EL devices, and can be simply represented as follows. The light emitting layers 95 of EL devices STD, A, B and C are all 30 nm in thickness, and doped with compound Ir-pytz in a concentration of 6 vol. %.

| | |
|---|---|
| Device STD | Glass substrate/ITO/HIL/HTL/Ir-ppz1 (0 nm)/6 vol. % of |
| (Com- | compound Ir-pytz: CDBP (30 nm)/ETL (45 nm)/LiF—Al |
| parison) | |
| Device A | Glass substrate/ITO/HIL/HTL/Ir-ppz1 (0.5 nm)/6 vol. % of |
| | compound Ir-pytz: CDBP (30 nm)/ETL (45 nm)/LiF—Al |
| Device B | Glass substrate/ITO/HIL/HTL/Ir-ppz1 (1.5 nm)/6 vol. % of |
| | compound Ir-pytz: CDBP (30 nm)/ETL (45 nm)/LiF—Al |
| Device C | Glass substrate/ITO/HIL/HTL/Ir-ppz1 (2.5 nm)/6 vol. % of |
| | compound Ir-pytz: CDBP (30 nm)/ETL (45 nm)/LiF—Al |

Device tests are conducted herein, and the results are presented in FIGS. 10, 11, 12, 13, 14A, 14B, 15 and 16.

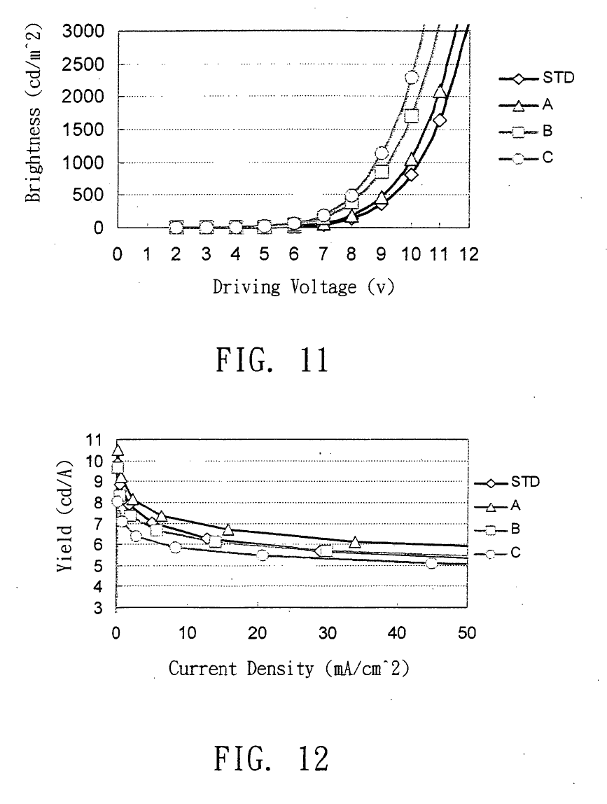

FIG. 10 depicts the variation of current density with voltage according to the first set of EL devices STD, A, B and C in the second example of the invention. FIG. 11 depicts the variation of brightness with voltage according to the first set of EL devices STD, A, B and C in the second example of the invention. The results of FIG. 10 and FIG. 11 indicated that the electron blocking layer 94 did improve physical properties of the EL device, and the injection ability of the electrons/holes of the EL devices increased with the thickness of the electron blocking layer 94. The results of FIG. 11 indicated that the brightness of the devices also increases with the thickness of the electron blocking layer 94. The device C generates the brightness of 1000 nits (cd/m²) when a driving voltage is about 8.8 V. However, higher driving voltages are required for the devices STD, A and B to generate the brightness of 1000 nits. Accordingly, the brightness of the device is also proportional to the thickness of the electron blocking layer 94.

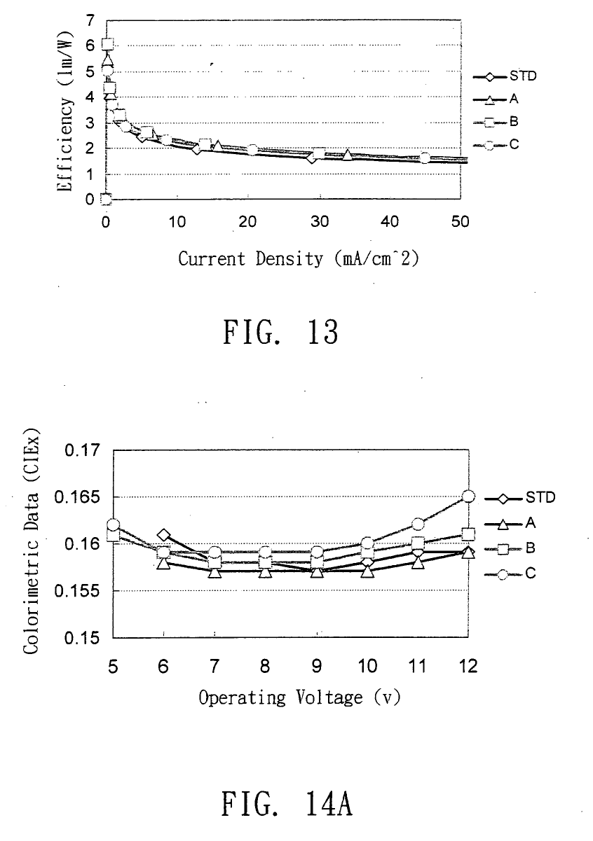

FIG. 12 depicts the variation of yield with current density according to the first set of EL devices STD, A, B and C in the second example of the invention. FIG. 13 depicts the variation of efficiency with current density according to the first set of EL devices STD, A, B and C in the second example of the invention. The results of FIG. 12 indicated that the device A (having a 0.5 nm electron blocking layer 94) has greatest yield (about 10.5 cd/A) than other devices. The yield of the STD device is about 9.8 cd/A only. The results of FIG. 13 indicated that the devices A, B and C (with the electron blocking layers 94) have better efficiencies. However, it shows no significant differences between the efficiencies of the STD device and the devices having the electron blocking layers 94. The electron blocking layer 94 with certain thickness may decrease the yield and the efficiency of the EL device. According to the experimental results, it is suggested that the thickness of the electron blocking layer 94 in the first set of EL device is preferably in a range of 0.5 nm to 2.5 nm. It is, of course, understood that the thickness of the electron blocking layer optionally varies in the practical applications; for example, it varies when other blue phosphorescent material is selected for making the light emitting later.

FIG. 14A depicts the variation of colorimetric data ClEx with voltage according to the first set of EL devices STD, A, B and C in the second example of the invention. FIG. 14B depicts the variation of calorimetric data ClEy with voltage according to the first set of EL devices STD, A, B and C in the second example of the invention. The results of FIG. 14A and FIG. 14B indicated that the calorimetric data ClEx and ClEy increase with the thickness of the electron blocking layer.

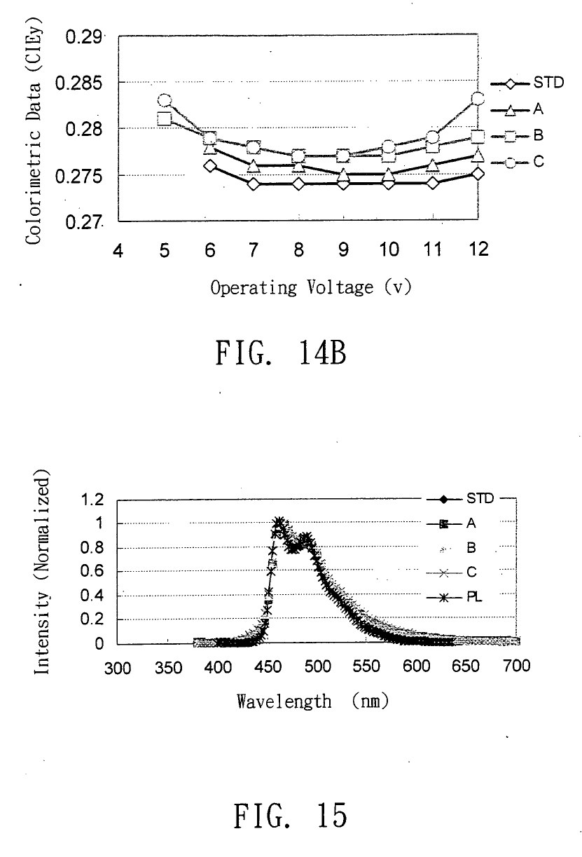

FIG. 15 represents the photoluminescence spectra of compound Ir-pytz and EL devices STD, A, B and C according to the first set of EL devices in the second example of the invention. The results of FIG. 15 indicated that the maximum wavelengths of compound Ir-pytz (curve “PL”) and the devices STD, A, B and C are almost the same, and the curves representing devices STD, A, B and C almost overlap. Accordingly, the existence of electron blocking layer has no significant effect on the photoluminescence of EL devices.

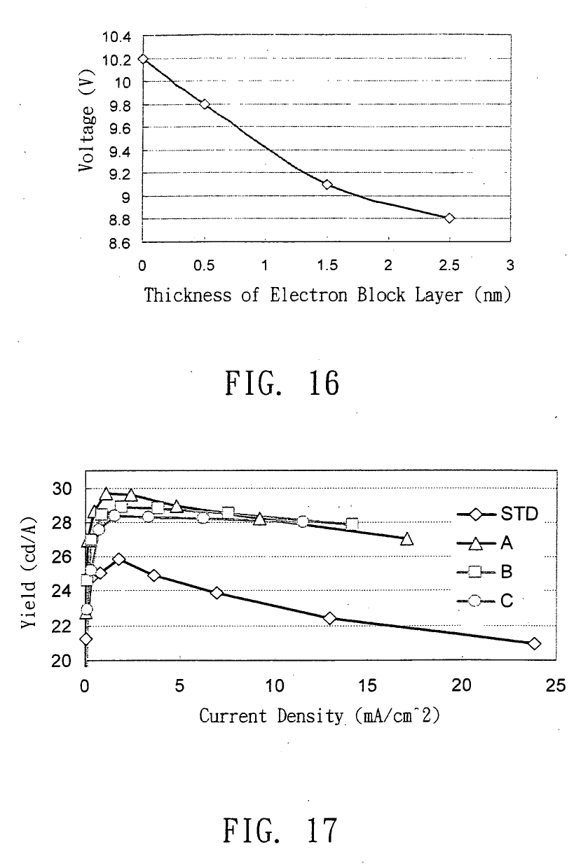

FIG. 16 depicts the variation of voltage with thickness of electron blocking layer according to the first set of EL devices STD, A, B and C in the second example of the invention, while the brightness of the EL devices achieve 1000 nits. The results of FIG. 16 indicated that the existence of electron blocking layer does has significant effect on the voltage required for the EL device to generate 1000 nits of brightness. The required voltage decreased with the thickness of the electron blocking layer. As shown in FIG. 16, the voltage is 10.2 v when no electron blocking layer is disposed in the EL device, and the voltage decreased to 8.8 v when 2.5 nm of electron blocking layer is disposed in the EL device.

The experimental results of the first set of EL devices STD, A, B and C in the second example, including light efficiency, voltage and current density while the EL device generates 1000 nits of brightness, are summarized in Table 2.

TABLE 2

| | Emission | | |
|---|---|---|---|
| | Efficiency or | Voltage (EL device @ | Current Density (EL |
| | emission yield | 1000 nits) | device @ 1000 nits) |
| EL device | (cd/A) | (v) | (mA/cm²) |
| STD | 9.8 | 10.2 | 13 |
| A | 10.5 | 9.8 | 14 |
| B | 9.7 | 9.1 | 17 |
| C | 8.1 | 8.8 | 20 |

Second Set of EL Devices (Emitting Green Light)

A second set of EL devices including the electron blocking layers made of compound Ir-ppz1 are constructed. Four organic EL devices emitting green light, including comparison device STD, devices A, B and C, are simply represented as follows.

| | |
|---|---|
| Device STD | Glass substrate/ITO/HIL/HTL/Ir-ppz1 (0 nm)/EML/ETL/ |
| (Com- | LiF—Al |
| parison) | |
| Device A | Glass substrate/ITO/HIL/HTL/Ir-ppz1 (3.0 nm)/EML/ETL/ |
| | LiF—Al |
| Device B | Glass substrate/ITO/HIL/HTL/Ir-ppz1 (4.5 nm)/EML/ETL/ |
| | LiF—Al |
| Device C | Glass substrate/ITO/HIL/HTL/Ir-ppz1 (5.0 nm)/EML/ETL/ |
| | LiF—Al |

FIG. 17 depicts the variation of yield with current density according to the second set of EL devices STD, A, B and C in the second example of the invention. The results of FIG. 17 indicated that the second set of EL devices STD, A, B and C had the yield of 25.9 cd/A, 29.8 cd/A, 28.4 cd/A and 27.5 cd/A, respectively. Accordingly, the electron blocking layer does significantly improve the yield of the EL device. According to the experimental results, it is suggested that the thickness of the electron blocking layer in the second set of EL device is preferably in a range of 0.5 nm to 5 nm. It is, of course, understood that the thickness of the electron blocking layer optionally varies in the practical applications; for example, it varies when other green phosphorescent material is selected for making the light emitting later.

Synthesis of Compound Ir-pytz

In the first set of EL devices, the compound Ir-pytz is respectively selected as the dopant of the light emitting layer 95 of EL devices.

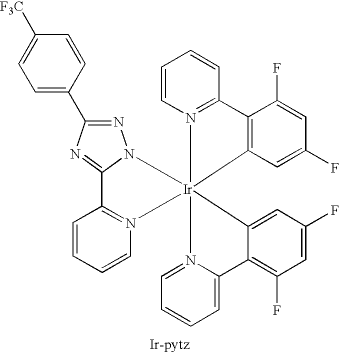

Compound Ir-pytz can be prepared by the following procedure.

(1) Referring to the reaction of scheme C-1. First, 15 ml (155.7 mmol) of 2-cyanopyridine and 30 ml (622.7 mmol) of hydrazine were dissolved in ethanol. The solution is mixed at a room temperature for 2 hours, and then the solvent was removed by a rotary condense. The residual was subjected to extraction with ethyl ether for three times, and then dehydrated by magnesium sulfate (MgSO₄). A light-yellow solid is obtained after the liquid is removed. Afterward, the light-yellow solid is re-crystallized using ethanol, and 16.5 g (121.5 mmol, yield 78%) of a hydrazidines precursor in the solid form (light-yellow color) is collected.

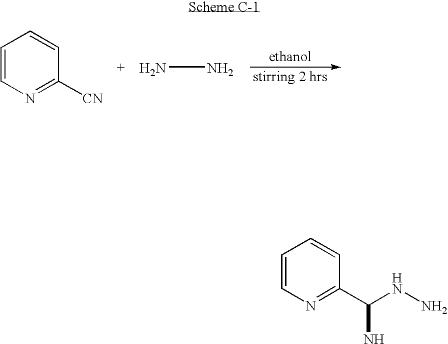

(2) Referring to the reaction of scheme C-2. 1.0 g (6.3 mmol) of 2,4-difluorophenyl boronic acid, 0.036 g (0.16 mmol) of palladium acetate (Pd(acetate)₂) and 0.28 g (0.24 mmol) of tetrakis(triphenylphosphine)palladium(0) were added to a reaction bottle containing 12 ml (2 M) of potassium carbonate (K₂CO₃) and 6 ml of 1,2-dimethoxyethane. Next, 0.6 ml (6.33 mmol) of 2-bromopyridine was added drop-by-drop into the reaction bottle, and the solution was refluxed for 24 hours. After cooling to room temperature, the solvent is drained from the reaction bottle to collect a yellow-brown solid. Then, the yellow-brown solid is dissolved in the water (about 60 ml), and extracted by dichloromethane (50 ml×2). The organic layer is dehydrated with sodium sulfate (Na₂SO₄), and the excess catalyzer and sodium sulfate are removed by a filtering plate. The solvent in the organic layer is then drained out by a rotating thickener to collect a crude product. Finally, a mixture solvent containing dichloromethane and hexane is used to re-crystallize the crude product to obtain 0.43 g (2.25 mmol, yield 36%) of light-yellow crystallized (2,4-difluoro-phenyl)-pyridine (abbreviated to 2,4-dfppy hereinafter).

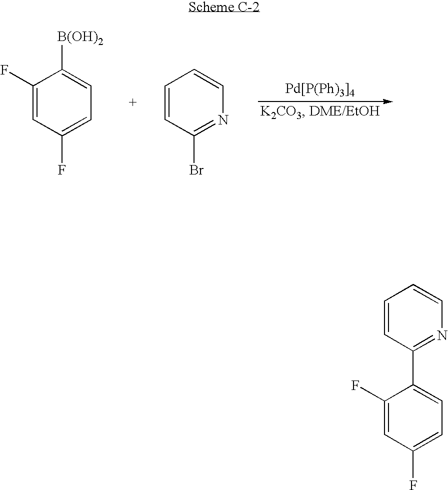

(3) Referring to the reaction of scheme C-3. 1.0 g (4.80 mmol) of 4-trifluoromethylbenzoyl chloride was dissolved in 10 ml of tetrahydrofuran (THF) contained in a first flask. 0.65 g (4.80 mmol) of hydrazidines and 0.65 g (4.80 mmol) of potassium carbonate (K₂CO₃) were dissolved in 40 ml of tetrahydrofuran (THF) contained in a second flask. Then, the solution in the firs flask was added drop-by-drop into the second flask, and precipitates were observed simultaneously. The chemical reaction continues for 6 hours. After filtering, the precipitates were washed with water followed by n-hexane for several times, vacuum dried, and then dissolved in ethylene golycol (EG). Afterward, the solution was refluxed for 30 minutes. After cooling to room temperature and standing on a bench for a while, the solid precipitates were observed. After filtering, the solid precipitates were collected, and washed with water followed by n-hexane for several times, and then vacuum dried to collect a crude product. The crude product is purified by sublimation to obtain 1.05 g (3.61 mmol, yield 74%) of ([3-(4-Trifluoromethyl-phenyl)]-5-(2-pyridyl)-1,2,4-triazole (abbreviated to CF₃-Ph-PytzH hereinafter).

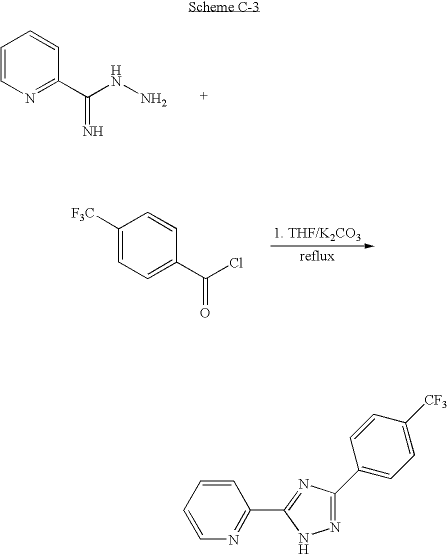

(4) Referring to the reaction of scheme C4. 3.0 g (8.52 mmol) of IrCl₃ and 3.74 g (19.6 mmol) of 2,4-dfppy synthesized in step (2) were added to a round-bottom flask containing a mixed solvent of 2-methoxyethanol and water (2-methoxyethanol:H₂O=3:1). The solution in the round-bottom flask was refluxed for 24 hours. Afterward, 20 ml of water is added to the round-bottom flask, and precipitate was observed. The resulting precipitate was filtered off, and washed with water followed by n-hexane, and then vacuum dried to collect 8.5 g (6.9 mmol, yield 82%) of [(24dfppy)₂Ir(μ-Cl)₂Ir(24dfppy)₂].

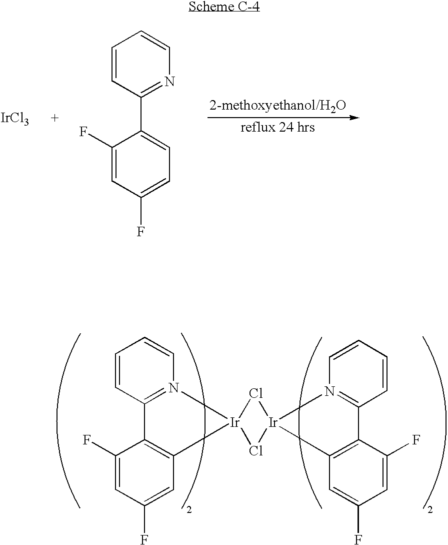

(5) Referring to the reaction of scheme C-5. 2.5 g (2.0 mmol) of [(24dfppy)₂Ir(μ-Cl)₂Ir(24dfppy)₂], 1.31 g (4.5 mmol) of CF₃-Ph-PytzH synthesized in step (3) and excess potassium carbonate (K₂CO₃) were added to a round-bottom flask containing 2-methoxyethanol (solvent). The solution in the round-bottom flask was refluxed for 16 hours. Afterward, 20 ml of water is added to the round-bottom flask, and precipitate was observed. The resulting precipitate was filtered off, and washed with water followed by n-hexane, and then vacuum dried to collect the crude product. The crude product is purified by sublimation to obtain 1.46 g (1.7 mmol, yield 85%) of Ir-pytz.

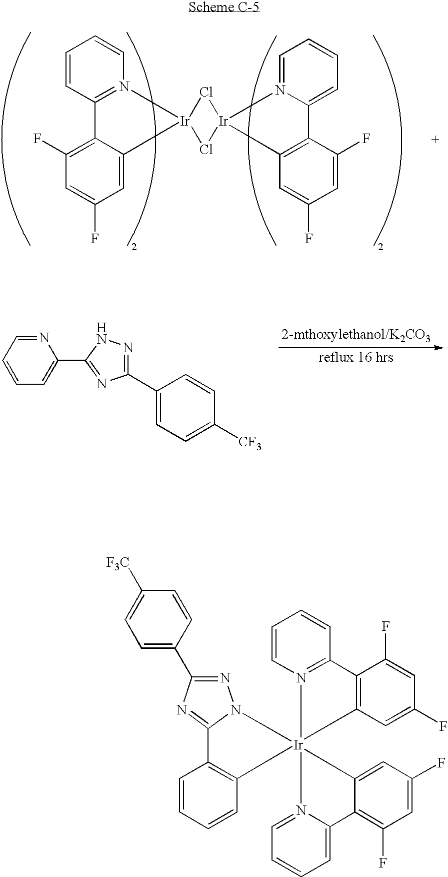

### THIRD EXAMPLE OF EL DEVICE

FIG. 2 also schematically illustrates an organic electroluminescence (OEL) device according to the third example of EL device of the invention. In the third example, four organic EL devices, including comparison device STD, devices A, B and C, are developed.

In the third example, the OEL device 20 mainly includes an anode 21, a light emitting layer 25 and a cathode 29. A glass substrate 211 with an indium tin oxide (ITO) film 212 was provided for making the anode 21. The cathode 29 could be a multi-metallic layer including lithium fluoride (LiF) and aluminum (Al). Also, a hole injection layer (HIL) 22 (optionally selected) and a hole transport layer (HTL) 23 are formed between the anode 21 and the light emitting layer 25. An electron transport layer (ETL) 27 and an electron injection layer (EIL) 28 (optionally selected) are formed between the cathode 29 and the light emitting layer 25.

In the EL devices of the third example, HTL 23 is made of the metal coordination compound Ir-ppz1, compounds CDBP (described in the first example) and Ir-pytz (blue phosphorescent material; described in the second example) are respectively selected as a host material and a dopant of the light emitting layer 25. The light emitting layers 25 of EL devices STD, A, B and C in the third example are all 30 nm in thickness, and doped with compound Ir-pytz in a concentration of 6 vol. %.

Also, the HTL 23 of the comparison EL device STD is made of compound N,N′-di-1-naphthyl-N,N′-diphenyl-1,1′-biphenyl-1,1′-biphenyl-4,4′-diamine (NPB).

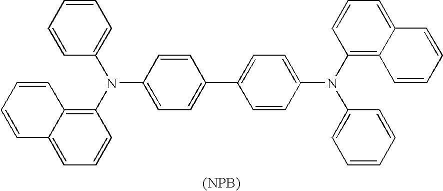

Four organic EL devices of the third example, including comparison device STD, devices A, B and C, are simply represented as follows.

| | |
|---|---|
| Device STD | Glass substrate/ITO/HIL/NPB/6 vol. % of |
| (Comparison) | Ir-pytz:CDBP (30 nm)/ETL (45 nm)/LiF—Al |
| Device A | Glass substrate/ITO/HIL/Ir-ppz1 (10 nm)/6 vol. % of |
| | Ir-pytz:CDBP (30 nm)/ETL (45 nm)/LiF—Al |
| Device B | Glass substrate/ITO/HIL/Ir-ppz1 (15 nm)/6 vol. % of |
| | Ir-pytz:CDBP (30 nm)/ETL (45 nm)/LiF—Al |
| Device C | Glass substrate/ITO/HIL/Ir-ppz1 (35 nm)/6 vol. % of |
| | Ir-pytz:CDBP (30 nm)/ETL (45 nm)/LiF—Al |

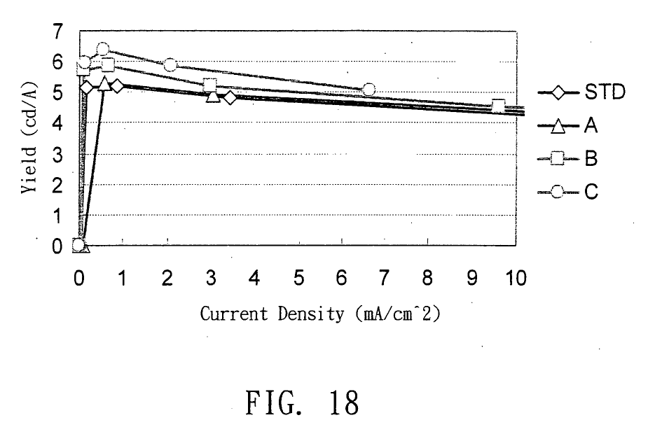

FIG. 18 depicts the variation of yield with current density of the EL devices STD, A, B and C according to the third example of the invention. The results of FIG. 18 indicated that the EL devices A, B and C (having the HTLs 23 made of compound Ir-ppz1) have better yield than the EL device STD (having the HTL 23 made of NPB). Also, the yield of the EL device increased with the thickness of the HTL 23 made of compound Ir-ppz1. According to FIG. 18, the device C (having 35 nm of Ir-ppz1) has the highest yield of about 6.5 cd/A, and the device B (having 15 nm of Ir-ppz1) has the second highest yield of about 6.0 cd/A.

While the present invention has been described by way of examples and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A metal complex represented by the formula: 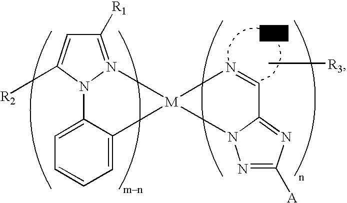
wherein M is a transition metal whose atomic number of the periodic table is greater than 40;
m is an integer equal to or smaller than a ligand number of M, and n is an integer smaller than m;
R₁, R₂, and R₃ are independently selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
Y₁ is an atomic group having a nitrogen-containing heterocyclic ring;
A is selected from the group consisting of a halogen atom, a cyano group, a phenyl group, a heterocyclic group, a CF₃ group, a substituted or unsubstituted C1-C30 alkyl group, a substituted or unsubstituted C₁-C30 alkoxy group, a hydroxy group, a thiol group, a substituted or unsubstituted C2-C30 alkenyl group, a substituted or unsubstituted C6-C30 aryl group, and a haloalkyl group.

2. The metal complex of claim 1, wherein M comprises osmium (Os), platinum (Pt), iridium (Ir), ruthenium (Ru), or rhenium (Re).

3. The metal complex of claim 2, wherein M is iridium (Ir) and a maximum wavelength of a luminescence spectrum of the metal complex in dichloromethane is about 490 nm.

4. An organic electroluminescence (OEL) device, comprising:
an anode;
a hole transport layer formed on the anode;
an organic light emitting layer, formed on the hole transport layer, including a metal complex represented by the formula: 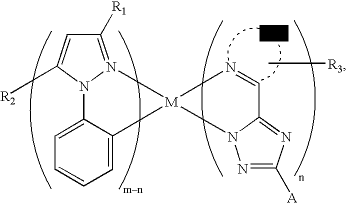
wherein M is a transition metal whose atomic number of the periodic table is greater than 40;
m is an integer equal to or smaller than a ligand number of M, and n is an integer smaller than m;
R₁, R₂, and R₃ are independently selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
Y₁ is an atomic group having a nitrogen-containing heterocyclic ring; and
A is selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
an electron transport layer formed on the organic light emitting layer; and
a cathode formed on the electron transport layer.

5. The device according to claim 4, wherein the metal complex is a dopant of the organic light emitting layer.

6. The device according to claim 4, wherein the metal complex has a volume concentration ranging from about 6% to about 9%.

7. The device according to claim 4, wherein M of the metal complex comprises osmium (Os), platinum (Pt), iridium (Ir), ruthenium (Ru), or rhenium (Re).

8. The device according to claim 7, wherein M of the metal complex is iridium (Ir), and a wavelength of a luminescence spectrum of the device ranges from about 480 nm to about 492 nm.

9. The device of claim 4, further comprising:
a hole injection layer disposed between the anode and the hole transport layer.

10. The device of claim 4, further comprising:
an electron injection layer disposed between the cathode and the electron transport layer.

11. An organic electroluminescence (OEL) device, comprising:
an anode;
a hole transport layer formed on the anode;
an electron blocking layer formed on the hole transfer layer, and the electron blocking layer including a metal complex represented by the formula: 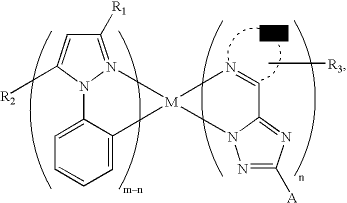
wherein M is a transition metal whose atomic number of the periodic table is greater than 40;
m is an integer equal to or smaller than a ligand number of M, and n is an integer smaller than m;
R₁, R₂, and R₃ are independently selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
Y₁ is an atomic group having a nitrogen-containing heterocyclic ring; and
A is selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
an organic light emitting layer formed on the electron blocking layer;
an electron transport layer formed on the organic light emitting layer; and
a cathode formed on the electron transport layer.

12. The device according to claim 11, wherein the electron blocking layer has a thickness ranged from about 0.5 nm to about 5.0 nm.

13. The device according to claim 11, wherein the organic light emitting layer has a dopant represented by the formula as below:

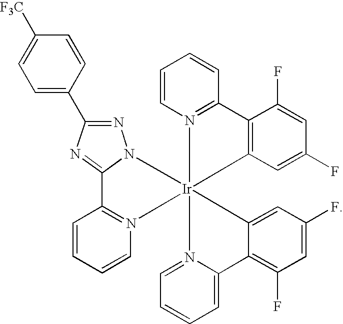

14. The device according to claim 13, wherein the dopant has a volume concentration ranged from about 6% to about 9%.

15. The device according to claim 11, wherein M of the metal complex comprises osmium (Os), platinum (Pt), iridium (Ir), ruthenium (Ru), or rhenium (Re).

16. The device of claim 11, further comprising:
a hole injection layer disposed between the anode and the hole transport layer.

17. The device of claim 11, further comprising:
an electron injection layer disposed between the cathode and the electron transport layer.

18. An organic electroluminescence (OEL) device, comprising:
an anode;
a hole transport layer, formed on the anode, including a metal complex represented by the formula: 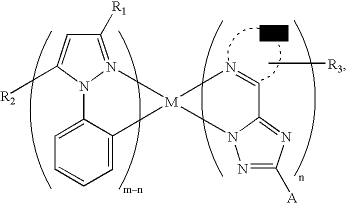
wherein M is a transition metal whose atomic number of the periodic table is greater than 40;
m is an integer equal to or smaller than a ligand number of M, and n is an integer smaller than m;
R₁, R₂, and R₃ are independently selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
Y₁ is an atomic group having a nitrogen-containing heterocyclic ring; and
A is selected from the group consisting of a halogen atom, a cyano group, a phenyl group, a heterocyclic group, a CF₃ group, a substituted or unsubstituted C1-C30 alkyl group, a substituted or unsubstituted C1-C30 alkoxy group, a hydroxy group, a thiol group, a substituted or unsubstituted C2-C30 alkenyl group, a substituted or unsubstituted C6-C30 aryl group, and a haloalkyl group;
an organic light emitting layer formed on the hole transport layer;
an electron transport layer formed on the organic light emitting layer; and
a cathode formed above the electron transport layer.

19. The device according to claim 18, wherein the hole transport layer has a thickness ranged from about 10 nm to about 35 nm.

20. The device according to claim 18, wherein M of the metal complex comprises osmium (Os), platinum (Pt), iridium (Ir), ruthenium (Ru), or rhenium (Re).

21. The device of claim 18, further comprising:
a hole injection layer disposed between the anode and the hole transport layer.

22. The device of claim 18, further comprising:
an electron injection layer disposed between the cathode and the electron transport layer.
